(19) United States
(12) Patent Application Publication
(10) Pub. No.: US 2024/0387543 A1
(43) Pub. Date: Nov. 21, 2024

(54) L-SHAPED FIELD EFFECT TRANSISTOR AND CORRESPONDING FABRICATION METHODS FOR ANGSTROM TECHNOLOGY NODES

(71) Applicants: National Cheng Kung University, Tainan (TW); NATIONAL YANG MING CHIAO TUNG UNIVERSITY, Hsinchu (TW)

(72) Inventors: YEONG-HER WANG, Tainan (TW); CHIN-CHENG HSIEH, Tainan (TW); CHIUNG-YI YANG, Tainan (TW); DARSEN DUANE LU, Tainan (TW); YAO-JEN LEE, Hsinchu (TW)

(21) Appl. No.: 18/656,915

(22) Filed: May 7, 2024

(30) Foreign Application Priority Data
May 19, 2023 (TW) 112118718

(51) Int. Cl. H01L 27/092; H01L 21/8238; H01L 23/528

(52) U.S. Cl. CPC H01L 27/0922; H01L 21/823807; H01L 23/528

(57) ABSTRACT

The proposed L-shaped field effect transistor comprises a horizontal FET and a vertical FET, wherein one end of the former is in contact with one end of the latter. Thus, the gates (or gate channels) of the two FETs can be separated by a distance so as to reduce mutual interference and simplify fabrication. When the two transistors are made of different materials, the contact area therebetween is small and the gates (or gate channels) of the two FETs are separated by a distance. Thus, the negative effect of interface defects close to the contact area can be reduced. To be compared to planar complementary FET (even FinFET and GAAFET), the proposed L-shaped FET can occupy a similar wafer area and have a similar overall thickness after subsequent metallization.

### CROSS REFERENCE

This non-provisional application claims priority of Taiwan Invention patent application No. 112118718, filed on May 19, 2023, the contents thereof are incorporated by reference herein.

### FIELD OF THE INVENTION

The present invention is a field-effect transistor (FET) and a corresponding manufacturing method applicable to the angstrom technology node, in particular, an L-shaped filed-effect transistor using an interconnected combination of a vertical field-effect transistor and a horizontal field-effect transistor and a corresponding manufacturing method.

### BACKGROUND OF THE INVENTION

As what the Moore's law states, the density of integrated circuits has been increasing in recent decades. The critical dimension (CD) used to evaluate the semiconductor components fabrication has decreased from the micron (micrometer) generation into the nanometer (nanometer) generation during the past years, even the commercialized integrated circuits have reached a few nanometers fabrication. Moreover, some studies have explored both structure and fabrication of the semiconductor components which uses angstrom as the unit of CD. In order to continuously reduce the critical dimension, especially to overcome some insurmountable difficulties encountered with the planar EFTs, in recent years, the three-dimensional FET has become the dominant design for commercialized integrated circuits (IC). FIG. 1 briefly presents the planar FET and three mainstream three-dimensional FETs.

Since Intel introduced the use of a three-dimensional fin field-effect transistor (FinFET) for the 22 nm process around 2012, FinFET has being commonly used to replace planar FET to further reduce the critical size of integrated circuits. One key is that the fin field-effect transistor has a larger effective width than the planar field-effect transistor and then current density is increased. Also, the three-dimensional structure increases channel control capability to suppress the short channel effect. However, along with the shrinkage of the critical dimension, the fin of FinFET are getting higher and thinner and then inevitably leads some problems, such as lower drive current strength, lower leakage current control, and higher performance variability.

Therefore, in recent years, the gate-all-around field-effect transistor (GAAFET) with vertically stacked nanosheets has been developed as a three-dimensional structure to compete with the fin field-effect transistor. It can provide a larger effective channel width which allows a larger drive current in the same wafer area than a fin field-effect transistor. By changing the size of used nanosheets, it can provide design flexibility to balance the requirements of increasing the drive current with the requirement of reducing the capacitance. Also, the design of the GAAFET allows the conduction channel to be completely surrounded by metal and/or materials with higher dielectric coefficients, and then it is possible to control the conduction channel more efficiently and shorten the length of the conduction channel. However, due to its complex structure, it is not yet commonly used in commercial ICs because the corresponding fabrication is more difficult and the specific design is more variable.

Besides, the complementary field-effect transistor (CFET) has been development in recent years to realize larger effective channel width and smaller overall dimension, as well as to reduce the difficulty of corresponding fabrications and designs. The basic concept of CFET is to stack a N-type field-effect transistor and a P-type field-effect transistor on top of each other. Thus, demand for smaller critical size can be met on the one hand, and excellent electrical performance can be achieved on the other hand. However, because two field-effect transistors are stacked vertically, both complex structure and fabrication difficulties are issues to be solved. For example, the two FETs may be formed on a N-type wafer and a P-type wafer respectively, and then how to stack them on top and bottom by bonding makes the fabrications more difficult. For example, since the gate channels of the two FETs are overlapped mutually, not only the thickness of the dielectric oxide bonded therebetween will degrade the electrical performance if it is too thick, but also there are non-negligible bonding defects (gaps) or even short circuits if it is too thin. Also, it is a challenge to form the contact required for the lower FET below, and also to provide different work functions for the gates of the upper and lower FETs respectively. How to modulate the work functions for the upper and lower gates electrodes is also a challenge. For example, when different materials (e.g., silicon and germanium) are used to balance the carrier mobility in P-type FET and N-type FET, how to deal with the lattice defects at the interface between the different materials is also a challenge.

Accordingly, in order to further reduce the critical dimension of integrated circuits, even to provide a better alternative to existing three-dimensional structures or to meet the future requirement that the critical dimension is reduced to less than one nanometer, it is necessary to develop new three-dimensional structure and corresponding fabrication.

### SUMMARY OF THE INVENTION

The present invention proposes an L-shaped field-effect transistor comprising a vertical field-effect transistor and a horizontal field-effect transistor. The former has a source, a gate and a drain arranged vertically, and the latter has a source, a gate and a drain arranged horizontally. Since one end of the horizontal field-effect transistor and one end of the vertical field-effect transistor are in mechanical contact with each other, the overall structure of the two transistors looks like the letter L, so the whole combination is named as an L-shaped field-effect transistor.

Significantly, the vertical field-effect transistor and the horizontal field-effect transistor do not overlap vertically as in the case of the complementary field-effect transistor. Hence, the density achieved by the L-shaped field-effect transistor is not much different from that of the complementary field-effect transistor, because the wafer area occupied by the vertical field-effect transistor is clearly smaller than that occupied by the horizontal field-effect transistor. In addition, since the vertical field-effect transistor and the horizontal field-effect transistor not only occupy different positions on the wafer but also one is always higher than the other, the manufacturing processes of them can be carried out separately. Thus, both the manufacturing process and the structure difficulty may be simplified. For example, the vertical field-effect transistor and the horizontal field-effect transistor not only basically do not overlap vertically (especially the gates or the gate channels of the two) but also mechanically contact each other only at one end. Thus, it is easy to make the contact and also adjust the work functions separately. For example, the horizontal field-effect transistor and the vertical field-effect transistor can be formed in different manufacturing processes or with different semiconductor materials. In particular, to be compared to the complementary FET where different channels are formed by different materials and then two different wafers (e.g., silicon wafers and germanium wafers) need to be stacked mutually through bonding to balance the carrier mobility of both the N-type and the P-type field effect transistors, the structure of the L-shaped field effect transistor allows one type of field effect transistor to be formed on one wafer (e.g., silicon wafer) before the other type to be formed by using other method(s). For example, the L-field transistor structure allows that one field-effect transistor is formed on a wafer (e.g., silicon wafer) and the semiconductor material (e.g., germanium) used by the other is formed on the wafer by other methods (e.g., epitaxial or deposition). Thus greatly simplifying overall process difficulties and structural complexity.

Significantly, the main feature of the L-shaped field-effect transistor is the L-shaped structure. Therefore, when the L-shaped FET is a combination of a horizontal field-effect transistor and a vertical field-effect transistor and also a combination of a P-type and a N-type, the L-shaped field-effect transistor does not restrict which FET is P-type and which FET is N-type. Further, when the N-type field-effect transistor and the P-type field-effect transistor are made of different materials respectively, the L-shaped field-effect transistor also does not restrict their respective materials or their respective formation methods. For example, two different field-effect transistors can be made of silicon and germanium respectively, or at least one field-effect transistor can be formed by using a single-crystal material formed by epitaxy or a material formed by molecular beam epitaxy, or at least one field-effect transistor can be formed by using a polycrystalline material formed by deposition, an oxide semiconductor material formed by deposition, a material formed by chemical vapor deposition, or a material formed by physical vapor deposition. In particular, since the horizontal field-effect transistor and the vertical field-effect transistor are in contact with each other only at their ends, the distance between the contact edge of the two FETS and the gates of the two FETs can be easily adjusted by adjusting the length of the two FETs and the gate positions of the two FETs. Hence, the negative effect of lattice defects or the like of the interfaces of the different materials on the gate (or viewed as the gate channels) of the two field-effect transistors can be minimized. For example, as a general rule, the thickness of lattice defects at the silica-perovskite interface is about 30 nanometers, so the negative effect of lattice defects at the silica-perovskite interface can be avoided by keeping the gate of the perovskite field-effect transistor at least 30 nanometers away from where the two field-effect transistors come into contact with each other. In addition, the gate size (or viewed as the size of the gate channel) of the horizontal field-effect transistor and the vertical field-effect transistor of the L-shaped field-effect transistor can be adjusted separately so as to adjust the performance of each of them. For example, the gate size of the vertical field effect transistor can be varied to simplify the process without increasing the occupied wafer area. Of course, it is possible to connect several L-shaped field-effect transistors in series with each other, or to connect one or more horizontal field-effect transistors with one or more vertical field-effect transistors in series with each other to form a multi-channels structure. For example, to mechanically connect different portions of a horizontal field-effect transistor to different vertical field-effect transistors respectively. In other words, the L-shaped field-effect transistor formed by combining a single horizontal field-effect transistor and a single vertical field-effect transistor can be used as a basic unit, and a plurality of L-shaped field-effect transistors can be assembled like building blocks to form a multi-channels structure with numerous gate channels. No special restriction is required to assemble a plurality of L-shaped field-effect transistors.

Incidentally, after forming a number of field-effect transistors, the integrated circuits fabrication requires a metallization process to form at least one metal conductor to connect the different field-effect transistors and to form a protective layer to protect these field-effect transistors from these metal connections. Therefore, when L-type field-effect transistors with vertical field-effect transistors are used, it actually does not clearly increase the whole thickness of the combination of the transistors, the metallization and the protective layer while it is compared to the complementary field-effect transistor or even other three-dimensional structures. In other words, there is no negative impact on the final integrated circuit product.

### BRIEF DESCRIPTION OF THE DRAWINGS

FIG. 1A to FIG. 1D illustrate the basic structure of a planar transistor and three mainstream cubic structure transistors.

FIG. 2A to FIG. 2B illustrate the basic structure of the L-type field-effect transistor proposed in the present invention.

FIG. 3 illustrates the basic flowchart of the L-type field-effect transistor manufacturing method proposed in the present invention.

FIG. 4A to FIG. 4B present a comparison between a complementary field-effect transistor and an L-type field-effect transistor.

FIG. 5A to FIG. 5B illustrate a specific design of an L-type field-effect transistor.

FIG. 6A to FIG. 6D illustrate a specific flowchart of an L-type field-effect transistor manufacturing method.

FIG. 7A to FIG. 7I illustrate a sample flow-chart of an integrated circuit with an L-shaped field-effect transistor.

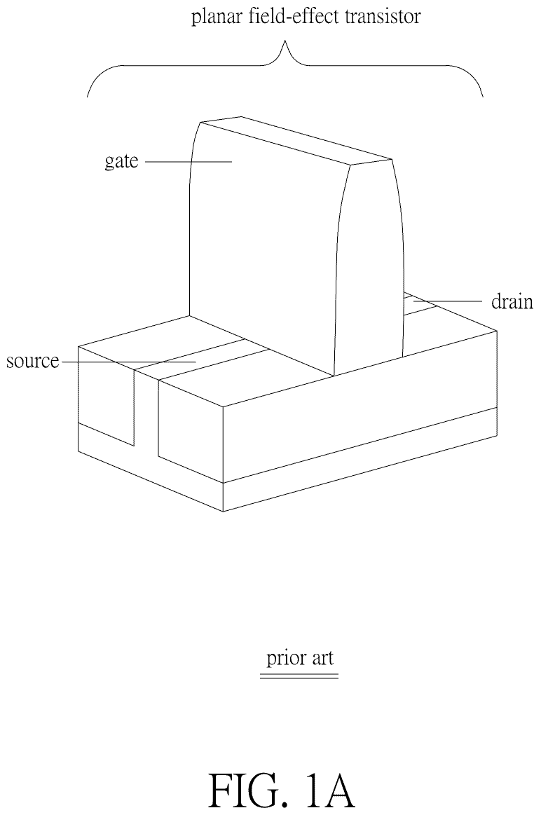

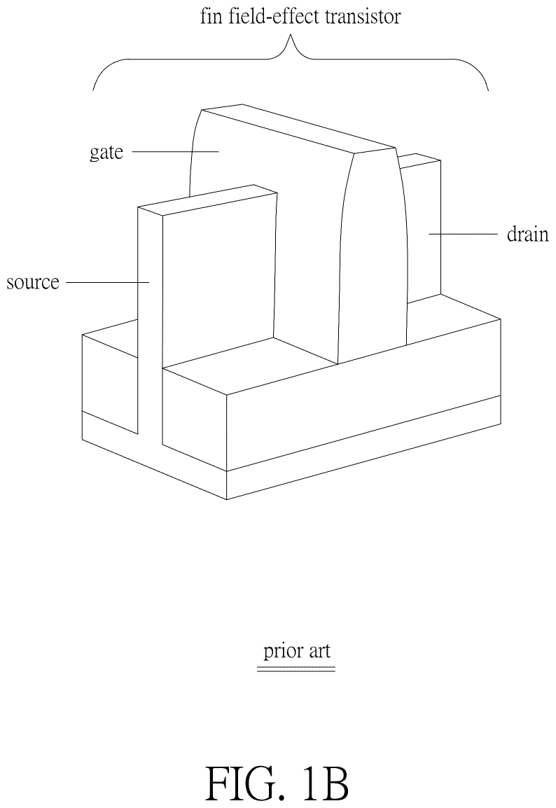

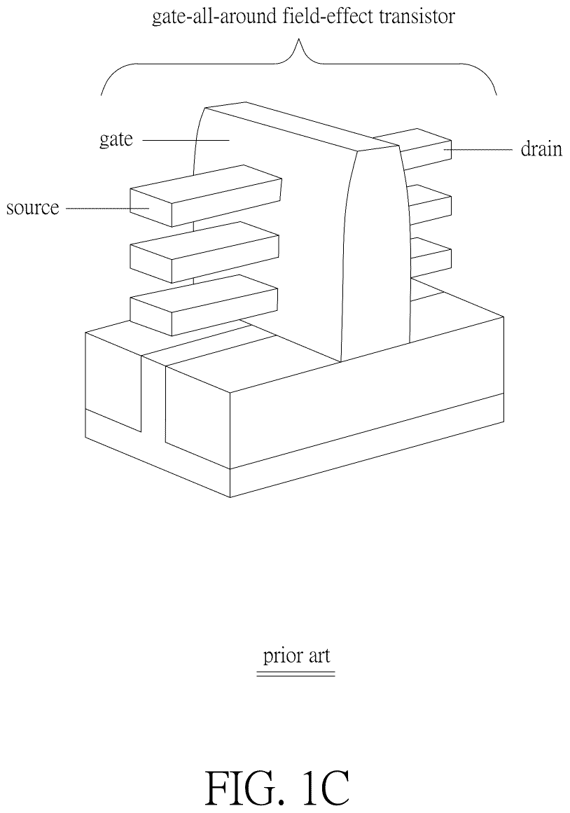

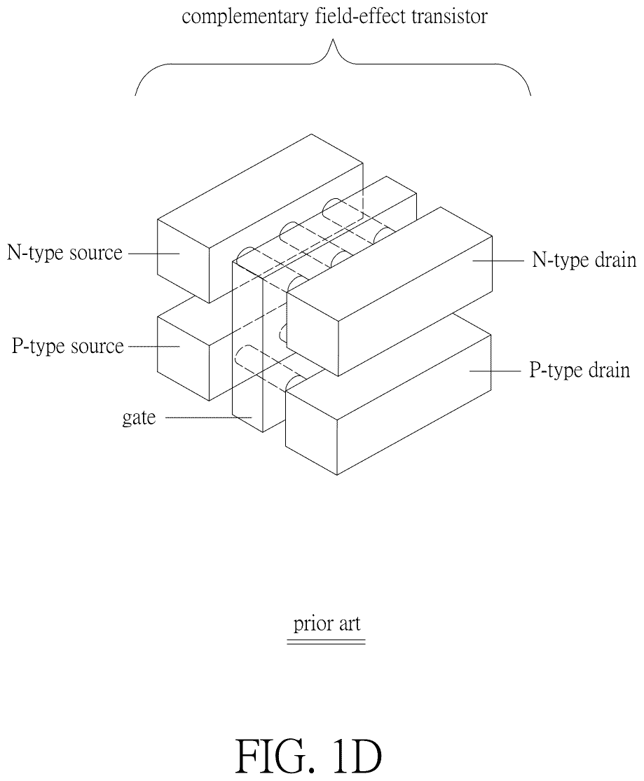

### DETAILED DESCRIPTION OF THE INVENTION

The detailed description and preferred embodiments of the invention are set forth in the following content and provided for people skilled in the art to understand the characteristics of the invention.

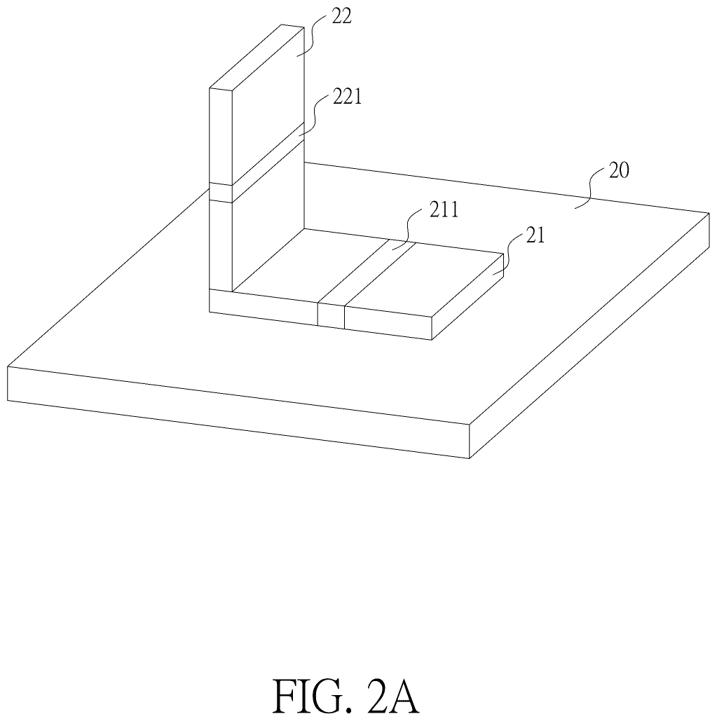

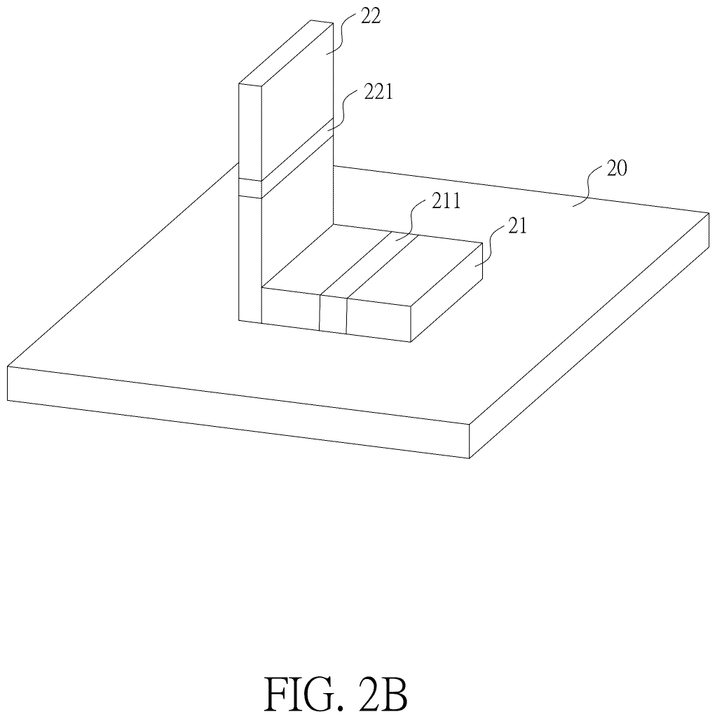

FIG. 2A and FIG. 2B present the essential structure of the L-shaped field-effect transistor proposed by the invention. Both the horizontal field-effect transistor 21 and the vertical field-effect transistor 22 are positioned on the same wafer 20, and one end of the horizontal field-effect transistor 21 is mechanically contacted with one end of the vertical field-effect transistor 22. The source, the gate 211 and the drain of the horizontal field-effect transistor 21 are horizontally arranged, and the source, the gate 221 and the drain of the vertical field-effect transistor 22 are vertically arranged. In this way, the horizontal field-effect transistor 21 and the vertical field-effect transistor 22, in particular the gate electrodes (or viewed as the gate channels) of the two, are essentially separate mutually and do not occupy the same portion of the wafer 20. Significantly, the horizontal field-effect transistor and the vertical field-effect transistor 22 form a L-shaped three-dimensional structure together, so it is named as a L-shaped field-effect transistor. The main feature of the L-shaped field-effect transistor is the L-shaped contour. The L-shaped field-effect transistor is a combination of the horizontal field-effect 21 transistor which is widely commercially used and the vertical field-effect transistor 22 which is under development. Hence, need not to limit the details of each of the horizontal field-effect transistor 21 and the vertical field-effect transistor 22. Not only their size, shape and materials. Not only dimensions, profiles, materials, and other details of the two themselves can be varied, but also the relative geometry of the two can be varied without violating the premise of the L-shaped structure. For example, the doping substances of each of the horizontal field-effect transistor 21 and the vertical field-effect transistor 22 is variable which means they can be the same or different from the other. Also, it needs not to limit which is P-type and which is N-type. For example, the distance between the gate 211 of the horizontal field-effect transistor 21 and the vertical field-effect transistor 22 can be different than the distance between the gate 221 of the vertical field-effect transistor 22 and the horizontal field-effect transistor 21, which means the two can have different sizes. For example, the material of the horizontal field-effect transistor 21 can be different than the material of the vertical field-effect transistor 22, which means the L-shaped field-effect transistor 29 can be a heterogeneous structure. For example, the vertical field-effect transistor 22 can be higher than the horizontal field-effect transistor 21 but also can be lower than the horizontal field-effect transistor 21, which means the L-shaped field-effect transistor 29 can be a positive L-shaped structure (as shown in FIG. 2A and FIG. 2B) or an inverted L-shaped structure (although not specifically illustrated).

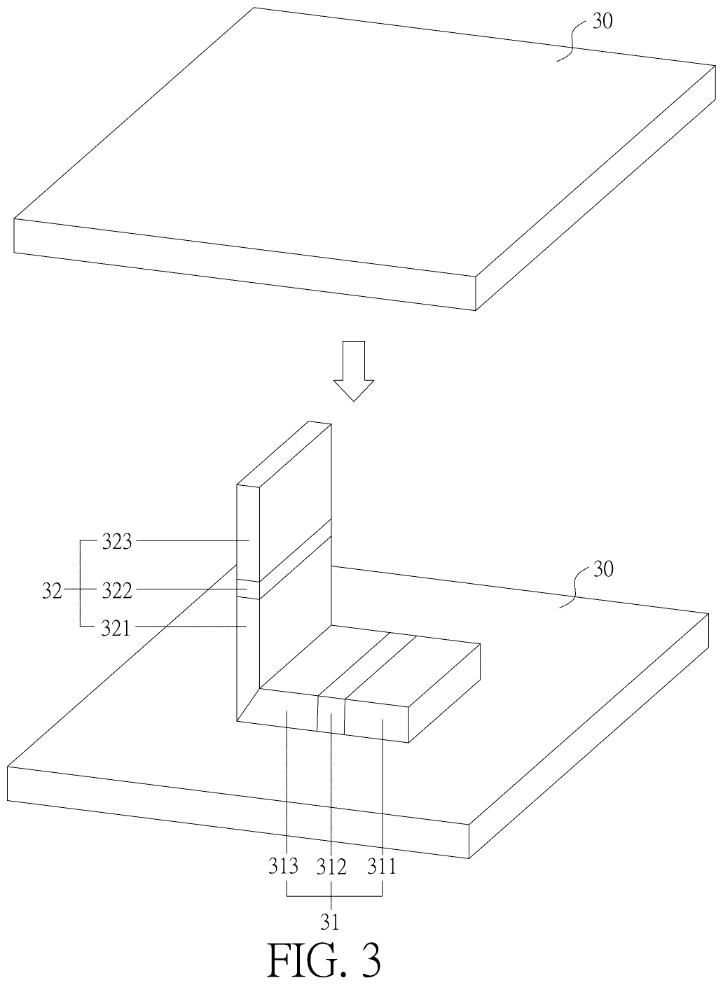

FIG. 3 presents the essential flowchart of a method of manufacturing a L-shaped field-effect transistor. Initially, provide the wafer 30. Next, form the horizontal field-effect transistor 31 and the vertical field-effect transistor 32 on the wafer 30. The source electrode 311, the gate electrode 312, and the drain electrode 313 of the horizontal field-effect transistor 31 are arranged horizontally, and the source electrode 321, the gate electrode 322 and the drain electrode 323 of the vertical field-effect transistor 32 are arranged vertically. Also, one end of the vertical field-effect transistor 32 is arranged to be mechanically contacted with one end of the horizontal field-effect transistor 31. Surely, FIG. 3 just is an example of manufacturing a certain type of the L-shaped field-effect transistor. The similar flowchart also can be used to form other L-shaped field-effect transistor. For example, to form the horizontal field-effect transistor 31 and the vertical field-effect transistor 32 both with a rectangular profile, or to form a vertical field-effect transistor 32 with a rectangular profile and a horizontal field-effect transistor 32 with the wider source 311, the wider drain 313 and the narrower gate 312. For example, the horizontal field-effect transistor 31 can be formed first or the vertical field-effect transistor 32 can be formed first. For example, it can form an L-type field-effect transistor having a positive L-type structure or it can form an L-type field-effect transistor having an inverted L-type structure.

Significantly, the L-shaped field-effect transistor proposed by the invention is a new three-dimensional field-effect transistor. The conventional three-dimensional field-effect transistors include the planar field-effect transistor, the FinFET, the GAAFET and the CEFT. Anyway, the invention mainly focuses on the difficulties encountered in the complementary field-effect transistor and then proposes new solutions.

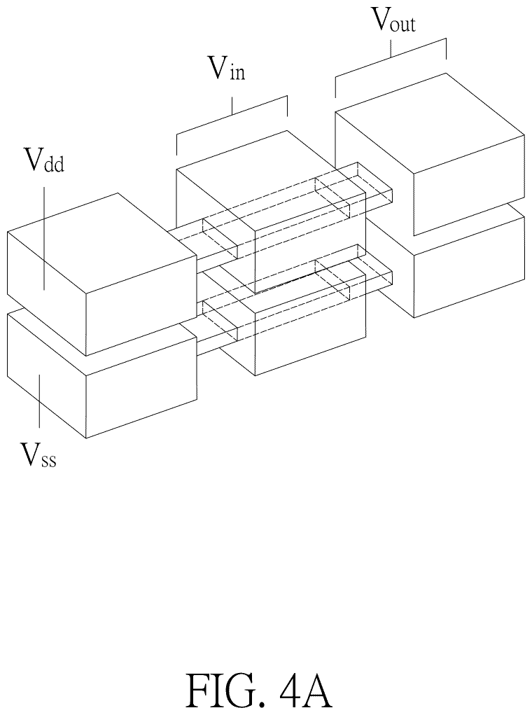

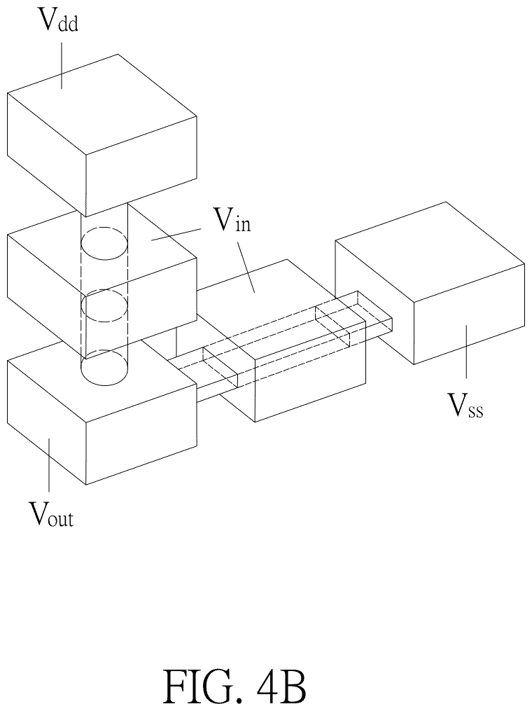

As shown in FIG. 4, the complementary field-effect transistor can be viewed a combination of two planar field-effect transistors stacked vertically mutually. The L-shaped field-effect transistor retains the use of two planar field-effect transistors, but changes the relative geometry of the two planar field-effect transistors to a horizontal one and a vertical one, wherein one end of the former is in mechanical contact with one end of the latter. That is to say, the L-shaped field-effect transistor allows the horizontal field-effect transistor and the vertical field-effect transistor share the same output voltage Vout, but allows the input voltage Vin (or viewed as gate), the source voltage Vss (or viewed as source) and the drain voltage Vdd (or viewed as drain) of the horizontal field-effect transistor are separated from that of the vertical field-effect transistor respectively.

The L-shaped field-effect transistor with a L-shaped structure proposed in the invention has at least the following advantages over the existing complementary field-effect transistor: same density, easily to form interconnecting contacts, easily to adjust the work function of the gate, and easily to form hetero-integration.

First of all, the wafer area occupied by a complementary field-effect transistor and an L-shaped field-effect transistor is almost the wafer area occupied by a horizontally field-effect transistor. In particular, the wafer area occupied by a vertical field-effect transistor is significantly smaller than the wafer area occupied by a horizontal field-effect transistor. That is, although the profile and the size of each field-effect transistor contained in both the complementary field-effect transistor and the L-shaped field-effect transistor can be adjusted, the wafer areas occupied by both are also equal if the profile and the size of the used field-effect transistor used in both are almost equal. Hence, even if the overall layout of the metal wires, the shallow trench isolation layer and others are different when the complementary field-effect transistor and the L-shaped field-effect transistor are used in the manufacture of memory or logic circuits respectively, the density of the integrated circuits using the complementary field-effect transistors and the density of the integrated circuits using the L-type field-effect transistors can be still approximately the same.

Also, compared to the complementary field-effect transistor where two planar field-effect transistors are separated away but overlap vertically each other, in the L-shaped field-effect transistor, the vertical field-effect transistor only overlaps vertically with one end of the horizontal field-effect transistor. That is, in the complementary field-effect transistor, to form the contact connected to the planar field-effect transistor located below is always affected by the planar field-effect transistor located above, and then it cannot be as undisturbed as when the contact is formed to be connected to the planar field-effect transistor located above. Unavoidably, it needs to occupy more wafer area and increases more difficulties in the manufacturing processes. In contrast, in the L-shaped field-effect transistor, the contact connected to the vertical field-effect transistor and the contact connected to the horizontal field-effect transistor can be formed separately without meaningful interference, especially when the drain electrode of the horizontal field-effect transistor essentially does not overlap the top and the bottom of the vertical field-effect transistor as illustrated in FIG. 2A and FIG. 2B. Hence, it is easy to form contact connected to the horizontal field effect transistor and the vertical field-effect transistor of the L-shaped field-effect transistor respectively without these unavoidable difficulties appeared during forming contact connected to the planar field-effect transistor located underneath in the complementary field effect transistor.

Further, in the complementary field effect transistor, two planar field-effect transistors vertically overlap each other and then the gate electrodes of each other also vertically overlap each other (or viewed as the gate electrodes of at least one of them vertically overlap the source electrodes or the drain electrodes of the other). But, in the L-shaped field-effect transistor, not only there is no vertically overlapping between gate electrodes of horizontal and vertical field-effect transistors, but also the gate electrodes of the horizontal field-effect transistor can not overlap the vertical field-effect transistors at all (unless the vertical field-effect transistors are deliberately tilted to extend above the horizontal field-effect transistors). That is, in the complementary field-effect transistor, the adjustment of the work function of the gate electrode of the planar field-effect transistor located below will inevitably be affected by the planar field effect transistor located above, and even the work function of the gate electrodes of the planar field-effect transistor located above will inevitably be affected. In contrast, in the L-shaped field-effect transistor, the adjustment of the work function of the gate electrode of the horizontal field-effect transistor and the adjustment of the work function of the gate electrode of the vertical field-effect transistor can be processed separately without interference with each other. Even, one field-effect transistor whose gate work function has already been adjusted properly will not be affected by the adjustment of the gate function of the other field-effect transistor. Therefore, compared to the complementary field-effect transistor, which is not easy to adjust the gate work functions of two planar field-effect transistors that overlap each other up and down, the L-shaped field effect transistor is easier to adjust the gate work functions of the vertical field-effect transistor and the horizontal field-effect transistor separately.

Moreover, when a P-type field-effect transistor and an N-type planar field-effect transistor are used to form the L-shaped Geld-effect transistor, in order to optimize their operations simultaneously, they are usually made of different materials so as to balance the mobility of holes and electrons. For example, they can be made of germanium and silicon respectively. Of course, when different materials are used, the material of any field-effect transistor can also be a single crystal material formed through epitaxial or molecular beam epitaxial, a polycrystalline material or an oxide semiconductor material formed through deposition. Also, it may be made of a material formed through chemical vapor deposition or physical vapor deposition, such as silicon, germanium, silicon germanium alloy, germanium tin alloy, gallium nitride, gallium arsenide, silicon carbide, indium gallium zinc oxide, tin oxide, or indium oxide formed by epitaxy, molecular beam epitaxy, deposition, chemical vapor deposition or physical vapor deposition. That is, the complementary field-effect transistors are often formed by overlapping a planar field effect transistor formed on a silicon wafer with a planar field-effect transistor formed on a gallium wafer. Usually, bonding is used to integrate the two wafers. However, besides the cost and the difficulty of bonding, the negative effect of lattice defects between the silicon wafers and the germanium wafers, especially on their respective gate channels, is a major problem. In contrast, in the L-shaped field-effect transistor, the vertical field-effect transistor and the horizontal field-effect transistor are formed on the same wafer, also the two field-effect transistors can be mechanically contacted mutually only at one end without thoroughly overlapping. Thus, it is possible to form one material on a wafer and to form another material by epitaxial, deposition, or other techniques on the wafer without covering an amount of wafer area by another material. For example, it is possible to form a vertically extending germanium structure on a silicon wafer by epitaxial molding, then form a vertical field-effect transistor on the germanium structure and a horizontal field-effect transistor on a portion of the silicon wafer in contact with the germanium structure. Of course, it is also possible to form a vertical field-effect transistor on a silicon wafer, and then form a horizontal field effect transistor by forming a section of a horizontally extended germanium material structure with epitaxial crystals on a portion of the silicon water in contact with the vertical field-effect transistor. By adjusting the size, profile, and gate position of the horizontal and vertical field-effect transistors respectively, the gate channels of the two field-effect transistors can be kept far away from the lattice defect regions between the different materials, and the size of the lattice defect regions where the two materials come into contact with each other can be greatly reduced. Therefore, compared to the complementary field effect transistor, the L-shaped field-effect transistor is suitable for heterogeneous integration and then the influence of lattice defects between heterogeneous materials can be minimized.

Furthermore, the L-shaped field-effect transistor has other advantages. For example, because the overlap ratio between the vertical field-effect transistor and the horizontal field-effect transistor is not large, the gate electrodes can be separated from each other by a certain distance, and the overlap area between the vertical field-effect transistor and wafers is not large, the L-shaped field-effect transistor can further reduce parasitic capacitance and electrical resistance. For example, the size of the gate channel of the vertical field-effect transistor can be enlarged in the direction perpendicular to the wafer surface to adjust the current that can pass through it without affecting the wafer area occupied by the vertical field-effect transistor. For example, in the complementary field-effect transistor, two planar field-effect transistors overlapping top and bottom are often not far apart, in particular, the gate (or viewed as the gate channels) of the two planar field-effect transistors are often not far apart, Thus, it is difficult to electrically isolate the two planar field-effect transistors, and then short circuits and other problems happens frequently. In the L-shaped field effect transistor, the distance between the horizontal field effect transistor and the vertical field effect transistor is farther, especially the distance between their gates or their gate channels. Thus, it is easier to carry out electrical isolation and to avoid short circuits or other problem.

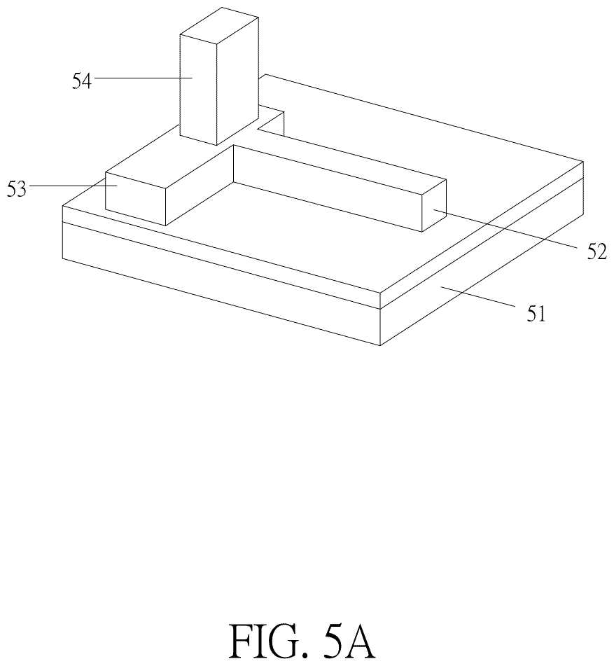

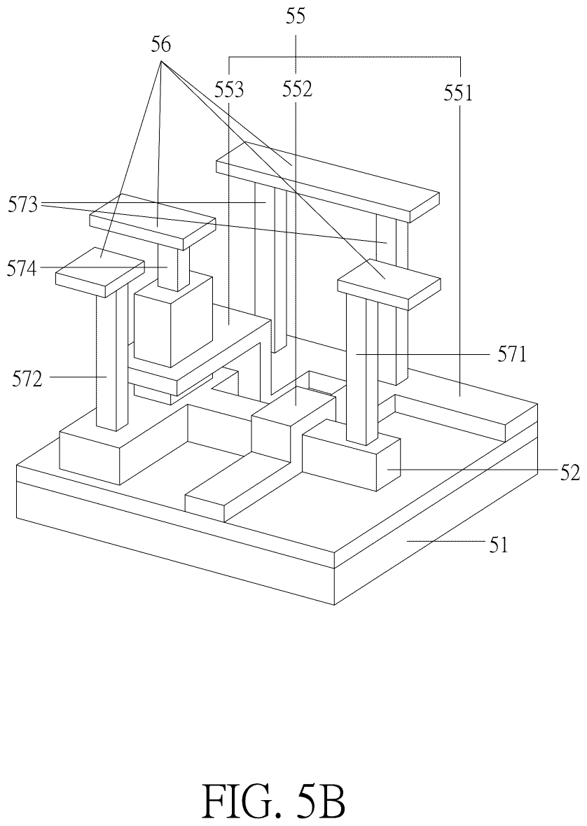

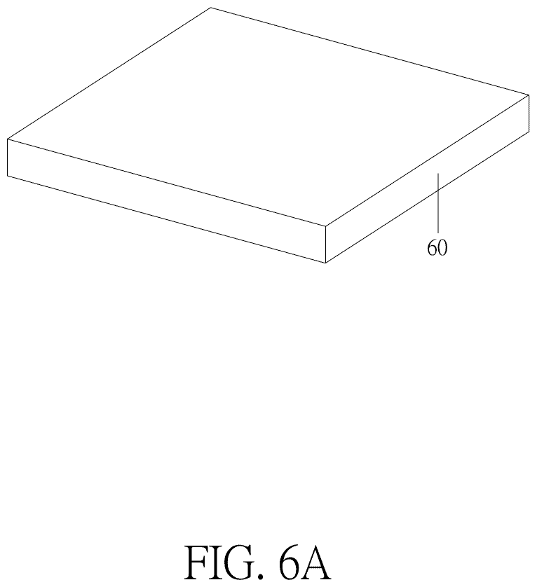

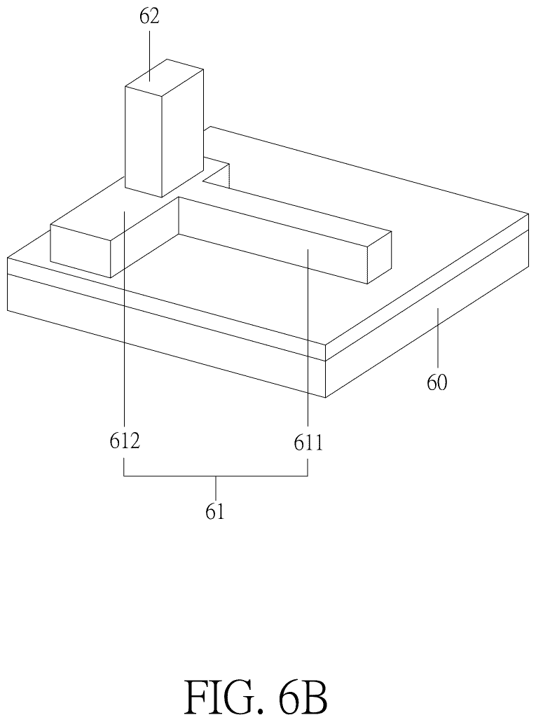

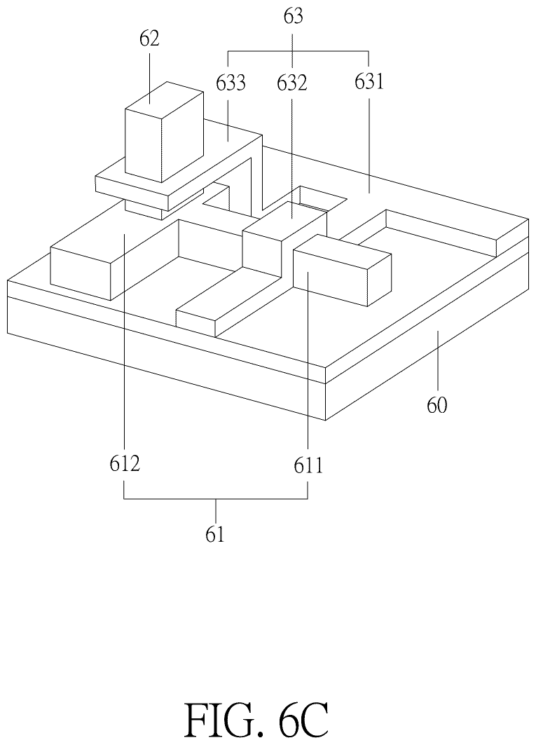

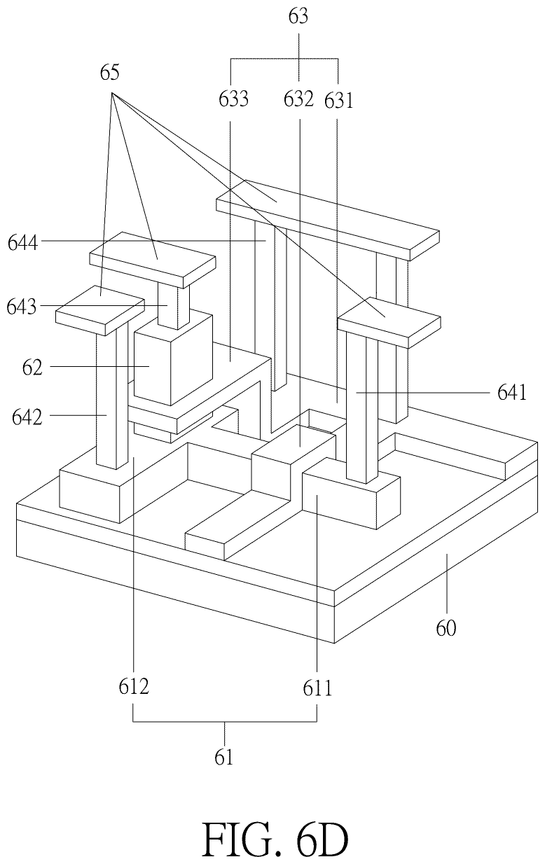

Moreover, without violating the requirement of the L-shaped contour, the L-shaped field-effect transistor and corresponding manufacturing method proposed in the invention can have many specific details and available variations. Just for example, FIGS. 5A˜5B illustrate a specific design of the L-shaped field-effect transistor, and FIGS. 6A˜6D illustrate a specific process of manufacturing an L-shaped field-effect.

FIG. 5A illustrates one kind of the L-shaped field-effect transistor proposed by the invention. It comprises a wafer 51, a first structure 62, a second structure 53, a third structure 54 and a fourth structure 55. Both the first structure 52 and the second structure 53 are positioned on the wafer and mechanically contacted mutually, and the third structure 54 is mechanically separated away both the wafer 51 and the first structure 52 and one end of the third structure 54 is mechanically contacted with the second structure 53. The fourth structure 55 can be divided into a first branch 551, a second branch 552 and a third branch 553. The first branch 551 is located on the wafer 51 and is mechanically separated away the first structure 52, the second structure 53 and the third structure 54. The second branch 552 is located on the wafer 51 and two ends of the second branch 552 are mechanically contacted with the first branch 551 and the first structure 52. One end of the third branch 553 is mechanically contacted with the first branch 551 and another end of the third branch 553 is mechanically separated away the second structure 53 but mechanically contacted with the third structure 54. The first structure 52, the second structure 53 and the third structure 54 are made of semiconductor material(s), which means their different portions can be used to be source, drain or channel controlled by gate. Whether the semiconductor materials used in each are the same is not specifically limited, also what kind(s) of the semiconductor material is used is not specifically limited. In addition to the common silicon, the semiconductor material also can be germanium or other III-V material or even II-VI material. The semiconductor material also can be silicon germanium alloy, germanium tin alloy, gallium nitride, gallium arsenide, silicon carbide, gallium zinc oxide, tin oxide or germanium oxide. How the semiconductor material is formed is not restricted. It can be formed by using deposition, chemical vapor deposition, physical vapor deposition, epitaxial, molecular-beam epitaxial or even others. Note that the material(s) of each of the first branch 551, the second branch 552 and third branch 55s includes both the dielectric material located below and the conductor material located above, i.e., they all can be used to form the gate.

Significantly, the first structure 52 and the second branch 552 forms together a horizontal field-effect transistor, and the third structure 53 and the third branch 553 forms together a vertical field-effect transistor. Particularly, both the specific relative geometrical relationship between the second branch 552 and the first structure 52 and the specific relative geometrical relationship between the third structure 54 and the third branch 553 can have a number of variations. That is, the specific design of the gate electrodes of each of the horizontal field-effect transistor and the vertical field-effect transistor can be varied, i.e., and the specific design is not limited to the situation shown in FIG. 5A. For example, regarding to the second branch 552 used as the gate of the horizontal field-effect transistor, as shown in FIG. 5A, it can be extended from the first branch 551 to and cross the first structure 52, and a special portion of the first structure 52 crossing the first structure 52 is mechanically contacted to the first structure 52. Anyway, the first branch 551 also can be only mechanically contacted with a side of the first structure 52 if it can properly apply voltage to a portion of the first voltage 52 being closed to the first branch 551. For example, regarding the third branch 553 used as the gate of the vertical field-effect transistor, one end can be mechanically contacted with the first branch 551 while another end surrounding and mechanically contacting the third structure 54. Anyway, the third branch 553 also can be only mechanically contacted with a side of the third structure 54 if it can properly apply voltage of a portion of the third structure 54 being closed to the third branch 553.

The relative geometrical relationship among the first structure 52, the second structure 53 and the third structure 54 can have more variations. For example, although FIG. 5A illustrates a situation that a T-shaped structure formed by the first structure 52 and the second structure 53 together, as long as the horizontal field-effect transistor and the vertical field-effect transistor can form an L-shaped field effect transistor together, in other non-illustrated variations, it is also possible that the first structure 52 and the second structure 53 together can form a zigzag structure, a X-shaped structure, a K-shaped structure, or any other shaped structure. For example, although FIG. 5A illustrates a situation with the most economical use of wafer area and most simplified structure: the mechanical contacted portion between the third structure 54 and the second structure 53 is overlapped with (or even is identical to) the mechanical contacted portion between the first structure 52 and the second structure 53, in other non-illustrated variations, the mechanically contacted portion between the third structure 54 and the second structure and the mechanically contacted portion between the first structure 52 and the second structure 53 can be in different portions of the second structure 53. For example, although FIG. 5A illustrates a situation that the first structure 52 has a rectangular profile that the width (or viewed as the cross-sectional area) of the gate channel, the source and the drain of the horizontal field-effect transistor is the same, in other non-illustrated variations, as long as the continuous shrinkage of the critical dimension, the width of the mechanically contacted portion between the first structure 52 and the second branch 552 can be lesser than the width of one end of the first structure 52 being not mechanically contacted with the second structure 53. For example, although FIG. 5A illustrates a situation that the third structure 54 has a rectangular profile that the width (or viewed as the cross-sectional area) of the gate channel, the source and the drain of the vertical field-effect transistor is the same, in other non-illustrated variations, as long as the continuous shrinkage of the critical dimension, the width of the mechanically contacted portion between the third structure 54 and the third branch 553 can be lesser than the width of one of two opposite ends of the third structure 54.

Significantly, because the main difference between the L-shaped field-effect transistor proposed by the invention and the current complementary field-effect transistor is the L-shaped structure formed by the combination of the horizontal field-effect transistor and the vertical field-effect transistor, other tails of the L-shaped field-effect transistor can have a number of variations. For example, when the L-shaped field-effect transistor is a combination of N-type field-effect transistor and a P-type field-effect transistor, it is acceptable that the N-type horizontal field-effect transistor is formed by the first structure 52 and the second branch 552 and the P-type field-effect transistor is a combination of the third structure 54 and the third branch 553, it is also acceptable that the P-type horizontal field-effect transistor is formed by the first structure 52 and the second branch 552 and the N-type field-effect transistor is a combination of the third structure 54 and the third branch 553. For example, when the L-shaped field-effect transistor is a heterogeneous structure made of different materials so as to balance the mobilities of carriers among the horizontal field-effect transistor and the vertical field-effect transistor. For example, it is possible that both the first structure 52 and the second structure 53 are made of silicon and the third structure 54 is made of germanium, but also is possible that both the first structure 52 and the second structure 53 are made of germanium and the third structure 54 is made of silicon. For example, each of the first structure 52, the second structure 53 and the third structure 54 can be made of at least one of the following: sing-crystal material formed by epitaxy, material formed by molecular beam epitaxy, polycrystalline material or oxide semiconductor formed by deposition, material formed by chemical vapor deposition, and material formed by physical vapor deposition. For example, each of the first structure 52, the second structure 53 and the third structure 54 can be made of at least one of the following materials formed by the above processes: silicon, germanium, silicon germanium alloy, germanium tin alloy, gallium nitride, gallium arsenide, silicon carbide, germanium oxide, tin oxide, and alumina. For example, the L-shaped field-effect transistor cam have L-shaped structure or inverse L-shaped structure, i.e., it is possible that the third structure 54 is high than the first structure 52 but also is possible that the first structure 52 is high than the third structure 54. Also, when the L-shaped field-effect transistor is a hetero-structure that the first structure 52 and the second structure 53 are made of the same material but the third structure 54 is different, in order to minimize the negative effects induced by these lattice defects distributed around the interface between different materials on the electric property of the vertical field-effect transistor, the distance between the second structure 53 and the contact portion between the third branch 553 and the third structure 54 is larger than the distribution range of these lattice defects induced by different materials around the contact portion between the third structure 54 and the second structure 53.

Additionally, as shown in FIG. 5B, the L-shaped field-effect transistor can further comprise one or more conductor lines formed during the metallization process so as to different portions of the L-shaped field-effect transistor 50 to different voltage source(s) and/or current source(s). In details, the conductor line structure 56 is located over and separated away all of the first structure 52, the second structure 53, the third structure 54 and the fourth structure 55. One end of a first conductive line 571 is mechanically contacted with the conductor line structure 56 and another of the first conductive line 571 only mechanical contacts with the first structure 52. One end of the second conductor line 572 is mechanically contacted with the conductor line structure 56 and another end of the second conductor line 572 only mechanically contacts with the second structure 53. The mechanical contact portion between the third structure and the second structure 53 is positioned between the mechanical contact portion between the second conductor line 572 and the second structure 53 and the mechanical contact portion between the first structure 52 and the second structure 53. One end of the third conductor line 573 is mechanically contacted with the conductor line structure 56 and another end of the third conductor line 573 only mechanically contacts with the first branch 551. One end of the fourth conductor line 574 is mechanically contacted with the conductor line structure 56 and another of the fourth conductor line 574 only mechanically contacts with the third structure 54. Surely, in the consideration of the configuration of the vertical field-effect transistor and the horizontal field-effect transistor, in general, the first conductive line 571 is connected to the source voltage terminal Vss, the second conductor line 572 is connected to the output voltage terminal Vout, the third conductor line 573 is connected to the input voltage terminal Vin, and the fourth conductor line 574 is connected to the drain voltage terminal Vdd.

Shown in FIG. 6A to FIG. 6C is the specific processes for manufacturing one kind of the L-shaped field-effect transistor proposed by the invention. Initially, as shown in FIG. 6A, provide a wafer 60. Next, as shown in FIG. 6B, form a first conductor material structure 61 and a second conductor material structure 62, wherein the former is positioned on the wafer 60 and includes a first branch 611 and a second branch 612 mechanically contacted mutually, wherein the latter only mechanically contacts with a portion of the second branch 612. And then, as shown in FIG. 6C, form a conductor-dielectric composite structure 63 comprising a third branch 631, a fourth branch 632, and a fifth branch 633, wherein the third branch 631 is positioned on the wafer 60 and mechanically separated away the first semiconductor material structure 61, wherein the fourth branch 632 is positioned on the wafer 60 also extended from the third branch 631 and then both crossed and mechanically contacted with the first branch 611, wherein the fifth branch 633 extends from the third branch 631 to the neighborhood of the second branch 612 and surrounding the second semiconductor material structure 62. Moreover, the fifth branch 633 is mechanically separated away the first semiconductor material structure 61, also each of the third branch 631, the fourth branch 632 and the fifth branch 633 is made of both the dielectric material located below and the conductor material located above. Clearly, the method of manufacturing a L-shaped field-effect transistor as illustrated in FIG. 6A to FIG. 6C is the method of manufacturing the L-shaped field-effect transistor as illustrated in FIG. 5A. That is to say, the first semiconductor material structure 61 corresponds to a major portion of the horizontal field-effect transistor, the second semiconductor material structure 62 corresponds to a major portion of the vertical field-effect transistor and the conductor-dielectric composite structure 63 corresponds to the gates of the two field-effect transistors. Hence, even different textual descriptions are used in different cases, as if different technical terminologies were used, the specific details of the commonality can be omitted without repeating, and the following is only a summary description.

At first, since a vertical field-effect transistor and a horizontal field-effect transistor are to be formed, the thickness of the second conductor material structure can be arranged to be greater than the thickness of the first semiconductor structure so as to increase the length of the vertical field-effect transistor in the direction vertical to the wafer surface. Although the desired L-shaped structure can be formed as long as the second semiconductor material structure is located on a portion of the first semiconductor material structure. Secondly, because the conductor dielectric composite structure 63 is used to provide the gate electrode, in order to adjust the length of vertical field-effect transistor, the thickness of the conductor dielectric composite structure 63 is often arranged to be less than the thickness of the second semiconductor material structure 62. For example, in order to simplify the manufacturing processes, the first semiconductor material layer and the second semiconductor material layer are often formed sequentially on the wafer 60, and then a first patterning process is carried out to transform the first semiconductor material layer into a first semiconductor material structure 61 and the second semiconductor material layer into a semiconductor material structure with the same profile as that of the first semiconductor material structure 61. After that, a second patterning process is carried out to further transform the second semiconductor material layer, which has already been treated in the first patterning process, into a second semiconductor material structure 62. Anyway, it is also optional to use epitaxy or other process to form a second conductor material structure 62 on a portion of a first semiconductor material structure 61 after the first semiconductor material structure 61 has been formed well.

Subsequently, one option is to arrange the material of the first semiconductor material structure 61 is an N-type semiconductor material and the material of the second semiconductor material structure 62 is a P-type semiconductor material, also another option is to arrange the material of the first semiconductor material structure 61 is a P-type semiconductor material and the material of the second semiconductor material structure is an N-type semiconductor material. Also, when the first semiconductor material structure 61 and the second semiconductor structure 62 are arranged to be made of different materials, these materials can be used to form each of them can be silicon, germanium, III-V materials, II-VI materials, single-crystal materials formed by epitaxy, materials formed by molecular-beam epitaxy, polycrystalline materials formed by deposition, oxide semiconductor materials formed by deposition, materials formed by chemical gas phase deposition, materials formed by chemical gas phase deposition, materials formed by physical vapor deposition, or even silicon, germanium, silicon germanium alloy, germanium tin alloy, gallium nitride, gallium arsenide, silicon carbide, gallium zinc nitride, tin oxide, or alumina formed by epitaxial, molecular beam epitaxial, deposition, chemical vapor deposition, or physical vapor deposition. In addition, one option is to arrange the first semiconductor material structure 61 to be higher than the second semiconductor material structure 62, and another option is to arrange the first semiconductor material structure 61 to be lower than the second semiconductor material structure 62.

Further, when the first semiconductor material structure 61 and the second semiconductor material structure 62 are made of different semiconductor materials, one option is to arrange the distance between the contact portion between the first branch 611 and the fourth branch 632 and the contact portion between the second branch 612 and the second semiconductor material structure 62 to be larger than the distribution range of lattice defects caused by the different semiconductor materials inside the second branch 612 and the first branch 611. Also, another option is to arrange the distance between where the fifth branch 633 surrounding the second semiconductor material structure 62 and the mechanically contact portion between the second semiconductor material structure 62 and the second branch 612 is larger than the distribution range of lattice defects induced by different semiconductor materials within the second semiconductor material structure 62.

Moreover, one option is that the second semiconductor material structure 62 is formed by using epitaxial technology when it is made of germanium, another option is that the first semiconductor material structure 61 is formed using epitaxial technology, and also one more option is to increase the thickness of a portion of the fifth branch 633 surrounding the second semiconductor material structure 62 without increasing the wafer area occupied by the second semiconductor material structure 62 so as to improve the short-channel effect. Alternatively, the thickness of a portion of the fifth branch 633 surrounding the second semiconductor material structure 62 may be increased without increasing the area of the wafer 60 occupied by the second semiconductor material structure 62 in order to improve the short channel effect. In addition, the mechanical contact portion between the second semiconductor material structure 62 and the second branch 612 can be overlapped with the mechanical contact portion between the first branch 611 and the second branch 612 so as to save the area of the wafer 60 occupied by the L-type field-effect transistor. Similarly, in response to the trend of continuous reduction of the critical size, in order to reduce the difficulty of the relevant process, one option is to arrange the first semiconductor material structure 61 to have a T-shape distribution on the wafer 60, also another option is to arrange the width of the mechanically contact portion between the first branch 611 and the fourth branch 632 to be less than the width of the end of the first branch 611 not in mechanical contact with the second branch 612, also another option is to arrange the width of the mechanically contact portion between the second semiconductor material structure 62 and the fifth branch 633 to be equal to the width of each end of the second semiconductor material structure 62.

Finally, as shown in FIG. 6D, a corresponding metallization process can be further carried out. That is to say, initially form a first conductor line 641 mechanically contacting only with the first branch 611 at one end, a second conductor line 642 mechanically contacting only with the second branch 612 at one end, a third conductor line 643 mechanically contacting only with the second semiconductor structure 62 at one end, and a fourth conductor line 644 mechanically contacting only with the conductor-dielectric composite layer 63 at one end. And then, form a conductor line structure 65 over and mechanically separated from the first semiconductor material structure 61, the second semiconductor material structure 62, and the conductor dielectric composite structure 63. The conductor line structure 65 mechanically contacts the other end of the first conductor line 641, the other end of the second conductor line 642, the other end of the third conductor line 643, and the other end of the fourth conductor line 644. The mechanically contact portion between the second semiconductor material structure 62 and the second branch 612 is closer to the mechanically contact portion between the first branch 611 and the second branch 612 than the mechanically contact portion between the second conductor line 642 and the second branch 612.

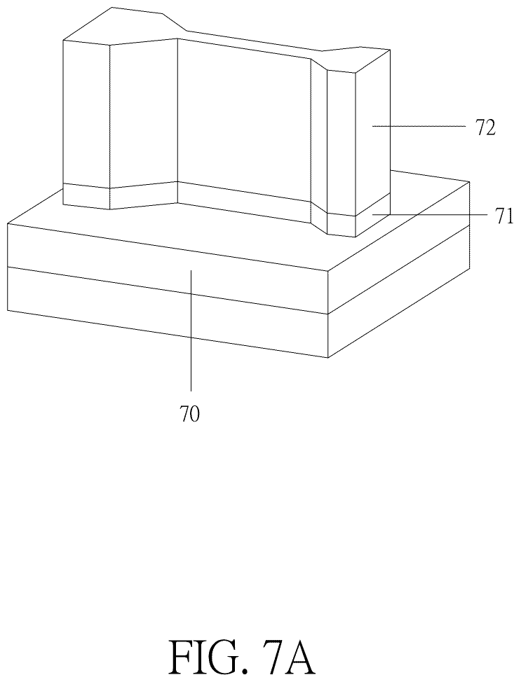

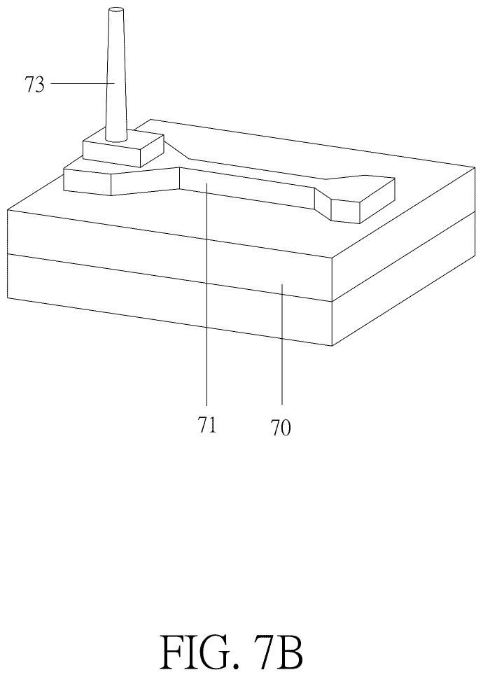

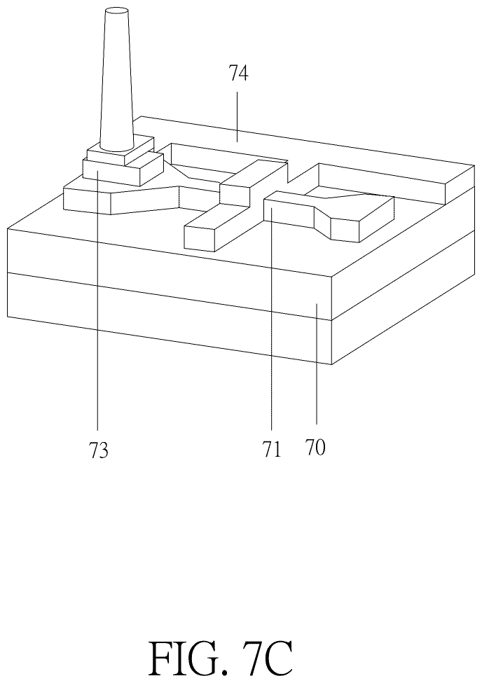

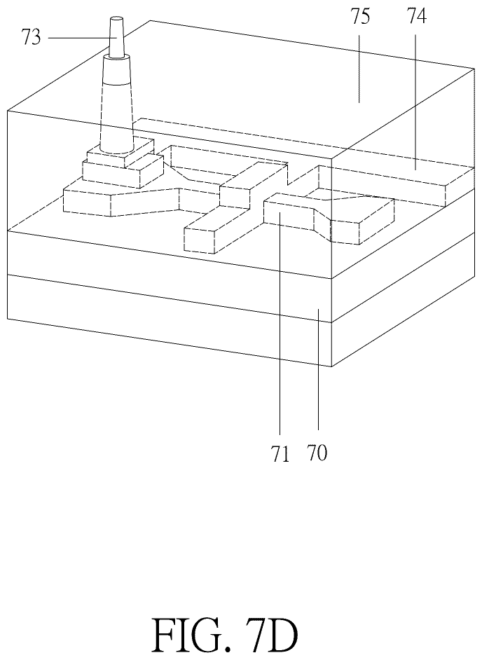

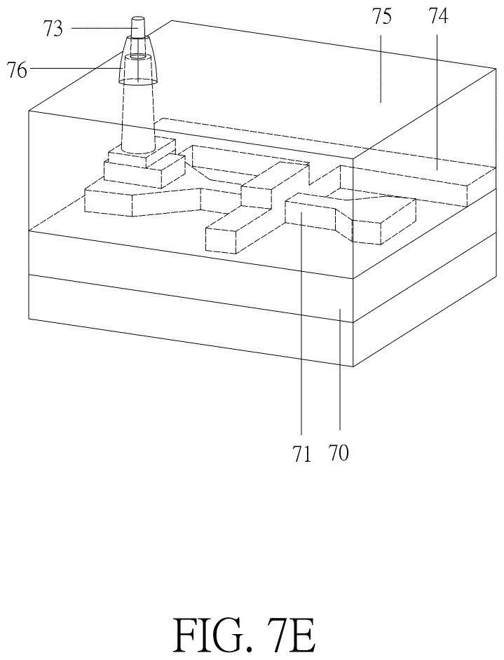

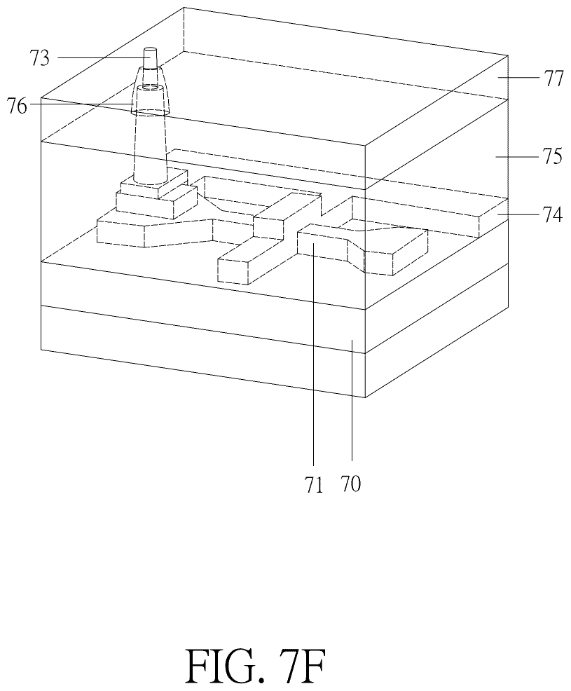

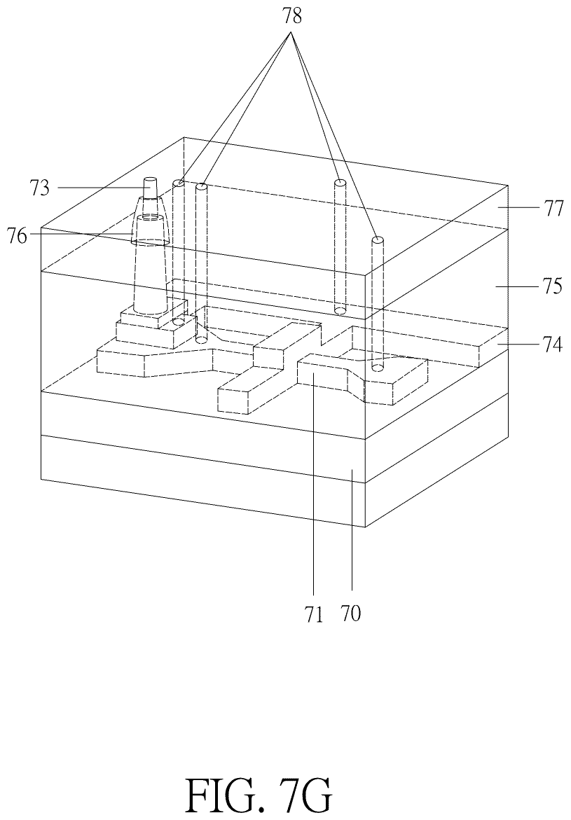

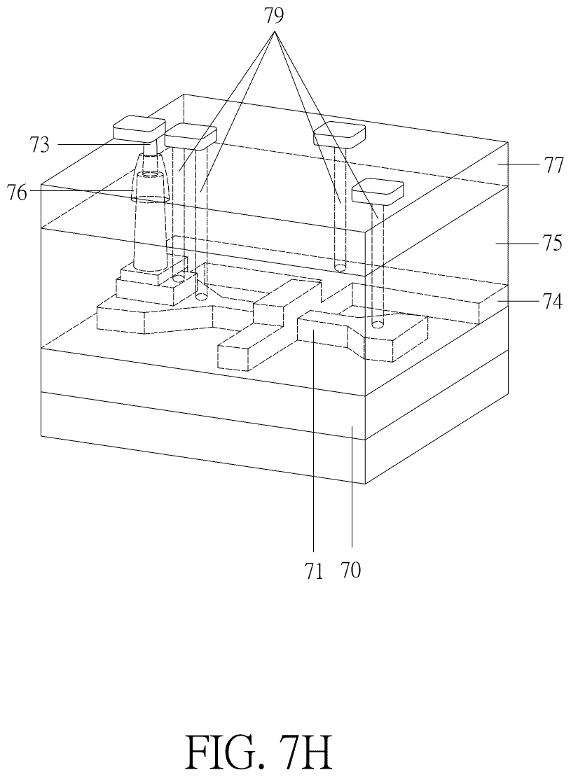

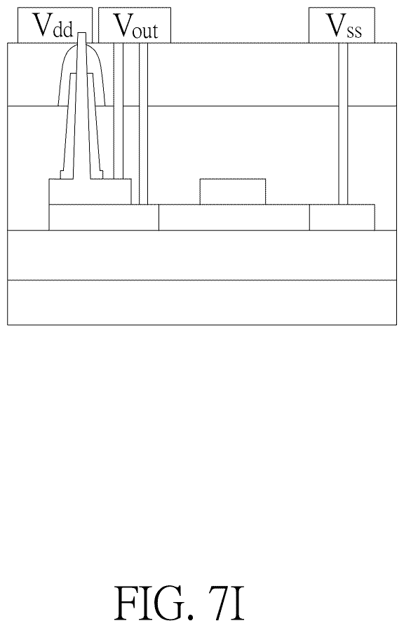

How to form an integrated circuit having the L-shaped field-effect transistor as proposed in the present invention can be archived by an amount of possible variations, also an amount of techniques capable of integrating a horizontal field-effect transistor or a vertical field-effect transistor into an integrated circuit can be applied. Just for example, as shown in FIG. 7A to FIG. 7I, an L-shaped field-effect transistor having a heterogeneous structure formed by silicon and germanium is present.

Initially, as shown in FIG. 7A, form both a silicon material structure 71 and a germanium material structure 72 on a wafer 70, wherein the two structures 71/72 have the same horizontal cross-sections and the horizontal cross-section profiles of both are wider at two ends and thinner in the middle. Then, as shown in FIG. 7B, the germanium material structure 72 is patterned to form a vertically extending patterned germanium material structure 73 on the horizontally extending silicon material structure 71, so that the patterned germanium material structure 73 can be used to form a vertical field-effect transistor and the silicon material structure 71 can be used to form a horizontal field-effect transistor. Essentially, the patterned germanium material structure 73 has a profile that is basically a long column tapering from bottom to top and a rectangular body located below the long column, and the horizontal cross-sectional area of the rectangular body is larger than the cross-sectional area of the long column. Next, as shown in FIG. 7C, a conductor dielectric composite structure 74 is formed on the wafer 70, wherein the conductor dielectric composite structure 74 can the gates of both a horizontal field-effect transistor and a vertical field-effect transistor so that both of them can be synchronously adjusted with respect to their gate voltages and gate channel conduction conditions. The conductor dielectric composite structure 74 is composed of a conductor material (usually metal) on the top and a dielectric material (usually high dielectric coefficient dielectric material) on the bottom. The conductor dielectric composite structure 74 does not completely cover the rectangular portion of the patterned germanium material structure 73. The thickness of the dielectric material is uniform, but the thickness of the conductor material is particularly thick in the portion of the patterned germanium material structure 73 and surrounds the rectangular portion of the patterned germanium material structure 73. And then, as shown in FIG. 7D, form a first spin-on glass layer 75 (or viewed as a protective layer) on the wafer 70 using the spin-on glass technique, wherein the first spin-on glass layer 75 covers the entire silicon structure 71 and most of the patterned germanium material structure 73. Then, flat the surface of the first spin-on glass layer 75 and remove the conductor material on the top portion of the uncovered patterned germanium material structure 73 (or viewed as removing the metal spacer). Thus, the top portion of the patterned germanium material structure 73 is exposed. After that, as shown in FIG. 7E, form a silicon nitride (SiN) gap wall 76 on the exposed top portion of the patterned germanium material structure 73. Next, as shown in FIG. 7F, form a second spin-coated glass layer 77 above the first spin-coated glass layer 75 and then flat the surface of the second spin-coated glass layer 77. Wherein, the silicon nitride (SiN) interstitial wall 76 is completely covered but the topmost portion of the germanium material structure 73 is uncovered, so as to form the topmost portion of the patterned germanium material structure 73 suitable for the subsequent metallization process. Subsequently, as shown in FIG. 7G, form several contact holes 78 in the second spin-coated glass layer 77 and the first spin-coated glass layer 75 so as to expose a portion of the conductor dielectric composite structure 74 used as the gate electrode(s), to expose a portion of a rectangular portion of the patterned germanium material structure 73 not covered by the conductor dielectric composite structure 74, and to expose a portion of each of the wider ends of the silicon material structure 71 used as a horizontal field-effect transistor. Finally, as shown in FIG. 7H, fill these contact holes 78 with the metal material to form some metal connections 79, and then form output voltage terminals Vout, input voltage terminals Vin, source voltage terminals Vss, and drain voltage terminals Vdd on top of each of the metal connections 79 to connect to the respective corresponding voltage/current sources. Wherein, FIG. 7I is a cross-sectional illustration related to a horizontal field-effect transistor formed by a silicon material structure 71 positioned on the wafer 70 and extended along the surface of the wafer 70.

As an aside, these contents shown in FIG. 7A to FIG. 7I are merely options used in the exemplary manufacturing method but are not fundamental limitations of the present invention. For example, the rectangular portion of the profile of the patterned germanium material structure 73 is used to absorb edge cracking of the patterned germanium material structure 73 inevitably caused by etching to remove unwanted dielectric or unwanted metal material during the subsequent formation of the conductor dielectric composite structure 74, so as to reduce the possibility of damage to the rectangular portion of the profile of the patterned germanium material structure 73, which is primarily used as a vertical field-effect transistor. For example, the silicon nitride gap wall 76 is used as an insulating protection to prevent any short circuit occurring in the subsequent metallization process. Anyway, if the metallization process can be controlled properly, it is also possible not to form the silicon nitride gap wall 76. One option is that directly arranges each contact hole to be located at a distance sufficiently large from the exposed top end of the patterned germanium material structure 73 so that the filling of metal into the contact holes does not cause the filled metal to be in contact with the patterned germanium material structure 73. That is, the filled metal is sufficiently far away from the exposed top of the patterned germanium structure 73, and then no short circuit therebetween will happen. For example, the vertical field-effect transistor can be a P-type field-effect transistor that a number of holes move on the (110) surface, and the horizontal field-effect transistor can be an N-type field-effect transistor that a number of electrons move on the (100) surface. For example, to form the desired N-type field-effect transistor and P-type field-effect transistor, an option is to dope numerous arsenic ions into the silicon material structure 71 and to dope numerous boron ions into the germanium material structure 72 respectively. For example, the conductor dielectric composite structure 74 can be a combination of a dielectric material made of alumina trioxide (Al₂O₃) and a conductor material made of titanium nitride (TiN).

As a short summary, in comparison with the existing complementary field-effect transistor, the L-shaped field-effect transistor proposed in the invention can have at least the following advantages: almost equal density, easier to form the mechanical contacts connected to each field-effect transistor in the L-shaped field-effect transistor respectively, easier to adjust the work functions of the gate electrodes of each of the two field-effect transistors contained therein respectively, and easier to carry out the heterogeneous integration of the two field-effect transistors contained therein by using different materials to form the two field-effect transistors. In addition, it is possible for the L-shaped field-effect transistor to have lower parasitic capacitance, to be easier to individually adjust the size and profile of the gate electrodes of each of the two included field-effect transistors, and so on. Therefore, although more development are required to optimize the details of the manufacturing processes and detailed structure for combining a horizontal field-effect transistor and a vertical field-effect transistor, the L-shaped field-effect transistor is indeed a new development in the series of three-dimensional structured field-effect transistors that includes the FinFET, the GAAFET, and the CFET, and has the potential to be applied to the products with the critical dimensions of only a few nm or even a few angstroms.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A L-shaped field-effect transistor, comprising:
A horizontal field-effect transistor, which is positioned on a wafer, wherein a source, a gate and a drain is horizontally arranged on the wafer; and
A vertical field-effect transistor, which is poisoned on the wafer, wherein a source, a gate and a drain is vertically arranged on the wafer;
wherein, one end of the vertical field-effect transistor is mechanically contacted with one end of the horizontal field-effect transistor.

2. The L-shaped field-effect transistor according to claim 1, further comprising at least one of the following:
the horizontal field-effect transistor is a N-type field effect transistor and the vertical field-effect transistor is a P-type field effect transistor;
the horizontal field-effect transistor is a P-type field effect transistor and the vertical field-effect transistor is a N-type field effect transistor;
the vertical field-effect transistor is higher than the horizontal field-effect transistor;
the vertical field-effect transistor is lower than the horizontal field-effect transistor;
the distance between the gate of the horizontal field-effect transistor and the position where the horizontal field-effect transistor contacts with the vertical field-effect transistor is larger than the distribution range of one or more lattice defects inside the horizontal field-effect transistor induced by different materials in contact with the vertical field-effect transistor when the horizontal field-effect transistor and the vertical field-effect transistor are made of different materials respectively; and
the distance between the gate of the vertical field-effect transistor and the position where the vertical field-effect transistor contacts with the horizontal field-effect transistor is larger than the distribution range of one or more lattice defects inside the vertical field-effect transistor induced by different materials in contact with the horizontal field-effect transistor when the vertical field-effect transistor and the horizontal field-effect transistor are made of different materials respectively.

3. The L-shaped field-effect transistor according to claim 1, further comprising at least one of the following:
the horizontal field-effect transistor is made of silicon and the vertical field-effect transistor is made of germanium;
the horizontal field-effect transistor is made of germanium and the vertical field-effect transistor is made of silicon;
at least one of the horizontal field-effect transistor and the vertical field-effect transistor is made of material selected from the group consisting of the following: single crystal materials formed by epitaxy, materials formed by molecular beam epitaxy, polycrystalline materials formed by deposition, oxide semiconductor materials formed by deposition, materials formed by chemical vapor deposition, materials formed by physical vapor deposition, and combinations thereof;
at least one of the horizontal field-effect transistor and the vertical field-effect transistor is made of material selected from the group consisting of the following: silicon formed by epitaxy, germanium formed by epitaxy, silicon germanium alloy formed by epitaxy, germanium tin alloy formed by epitaxy, gallium nitride formed by epitaxy, gallium arsenide formed by epitaxy, silicon carbide formed by epitaxy, germanium oxide formed by epitaxy, tin oxide formed by epitaxy, alumina formed by epitaxy, and combinations thereof;
at least one of the horizontal field-effect transistor and the vertical field-effect transistor is made of materials selected from the group consisting of the following: silicon formed by molecular beam epitaxy, germanium formed by molecular beam epitaxy, silicon germanium alloys formed by molecular beam epitaxy, germanium tin alloys formed by molecular beam epitaxy, gallium nitride formed by molecular beam epitaxy, gallium arsenide formed by molecular beam epitaxy, silicon carbide formed by molecular beam epitaxy, gallium oxide formed by molecular beam epitaxy, tin oxide formed by molecular beam epitaxy, and platinum oxide formed by molecular beam epitaxy and combinations therefore;
at least one of the horizontal field-effect transistor and the vertical field-effect transistor is made of material selected from the group consisting of the following: silicon formed by chemical vapor deposition, germanium formed by chemical vapor deposition, silicon germanium alloys formed by chemical vapor deposition, germanium tin alloys formed by chemical vapor deposition, gallium nitride formed by chemical vapor deposition, gallium arsenide formed by chemical vapor deposition, silicon carbide formed by chemical vapor deposition, gallium oxide formed by chemical vapor deposition, tin oxide formed by chemical vapor deposition, platinum oxide formed by chemical vapor deposition, and combinations thereof; and
at least one of the horizontal field-effect transistor and the vertical field-effect transistor is made of material selected from the group consisting of the following: silicon formed by physical vapor deposition, germanium formed by physical vapor deposition, silicon germanium alloys formed by physical vapor deposition, germanium tin alloys formed by physical vapor deposition, gallium nitride formed by physical vapor deposition, gallium arsenide formed by physical vapor deposition, silicon carbide formed by physical vapor deposition, gallium oxide formed by physical vapor deposition, tin oxide formed by physical vapor deposition, platinum oxide formed by physical vapor deposition, and combinations thereof.

4. A L-shaped field-effect transistor, comprising:
a first structure, which is located on a wafer;
a second structure, which is located on the wafer and mechanically contacts with the first structure;
a third structure, which is mechanically separately away the wafer and the first structure, wherein one end of the third structure is mechanically contacts with the second structure; and
a fourth structure, comprising:
a first branch, which is positioned on the wafer and mechanically separately away the first structure, the second structure and the third structure;
a second branch, which is positioned on the wafer, wherein one end of the second branch is mechanically contacted with the first branch and another end of the second branch is mechanically contacted with the first structure; and
a third branch, wherein one end of the third branch is mechanical contacted with the first branch and another end of the third branch is mechanically separated away the second structure but is mechanically contacted with the third structure;
wherein, material of the first structure, the second structure the third structure are semiconductor material;
wherein, material of the first branch, the second branch and the third branch includes the dielectric material located at the bottom and the conductor material located at the top.

5. The L-shaped field-effect transistor according to claim 4, further comprising at least one of the following:
the second branch extends on the wafer from the first branch to and across the first structure, also the second branch mechanically contacts with the first structure at where it crosses the first structure; and
one end of the third branch is mechanically contact with the first branch, also another end of the third branch surrounds the third structure end and is mechanically contacted with the third structure at where it surrounds the third structure.

6. The L-shaped field-effect transistor according to claim 4, further comprising at least one of the following:
the first structure and the first branch forms a N-type horizontal field-effect transistor, also the third structure and the third branch forms a P-type vertical field effect transistor;
the first structure and the first branch forms a P-type horizontal field-effect transistor, also the third structure and the third branch forms a N-type vertical field effect transistor;
the third structure is higher than the first structure;
the first structure is higher than the third structure;
when the materials of the first structure and the second structure are the same but the material of the third structure is different, the distance between the contact portion of the first branch and the first structure and the contact portion of the second structure and the third structure is larger than the distribution range of lattice defects in the first structure at the contact portion of the first structure with the third structure and also the distribution range of lattice defects in the second structure at the contact portion of the second structure with the third structure; and
when the material of the first structure and the material of the second structure is the same but is material of the third structure is different, the distance between the second structure and the contact portion between the third branch and the third structure is larger than the distribution range of lattice defects in the third structure at the contact portion of the third structure with the second structure.

7. The L-shaped field-effect transistor according to claim 4, further comprising at last one of the following:
the first structure and the second structure are made of silicon and the third structure is made of germanium;
the first structure and the second structure are made of germanium and the third structure is made of silicon;
at least one of the horizontal field-effect transistor and the vertical field-effect transistor is made of material selected from the group consisting of the following: single crystal materials formed by epitaxy, materials formed by molecular beam epitaxy, polycrystalline materials formed by deposition, oxide semiconductor materials formed by deposition, materials formed by chemical vapor deposition, materials formed by physical vapor deposition, and combinations thereof;
at least one of the horizontal field-effect transistor and the vertical field-effect transistor is made of material selected from the group consisting of the following: silicon formed by epitaxy, germanium formed by epitaxy, silicon germanium alloy formed by epitaxy, germanium tin alloy formed by epitaxy, gallium nitride formed by epitaxy, gallium arsenide formed by epitaxy, silicon carbide formed by epitaxy, germanium oxide formed by epitaxy, tin oxide formed by epitaxy, alumina formed by epitaxy, and combinations thereof;
at least one of the horizontal field-effect transistor and the vertical field-effect transistor is made of materials selected from the group consisting of the following: silicon formed by molecular beam epitaxy, germanium formed by molecular beam epitaxy, silicon germanium alloys formed by molecular beam epitaxy, germanium tin alloys formed by molecular beam epitaxy, gallium nitride formed by molecular beam epitaxy, gallium arsenide formed by molecular beam epitaxy, silicon carbide formed by molecular beam epitaxy, gallium oxide formed by molecular beam epitaxy, tin oxide formed by molecular beam epitaxy, and platinum oxide formed by molecular beam epitaxy and combinations therefore;
at least one of the horizontal field-effect transistor and the vertical field-effect transistor is made of material selected from the group consisting of the following: silicon formed by chemical vapor deposition, germanium formed by chemical vapor deposition, silicon germanium alloys formed by chemical vapor deposition, germanium tin alloys formed by chemical vapor deposition, gallium nitride formed by chemical vapor deposition, gallium arsenide formed by chemical vapor deposition, silicon carbide formed by chemical vapor deposition, gallium oxide formed by chemical vapor deposition, tin oxide formed by chemical vapor deposition, platinum oxide formed by chemical vapor deposition, and combinations thereof; and
at least one of the horizontal field-effect transistor and the vertical field-effect transistor is made of material selected from the group consisting of the following: silicon formed by physical vapor deposition, germanium formed by physical vapor deposition, silicon germanium alloys formed by physical vapor deposition, germanium tin alloys formed by physical vapor deposition, gallium nitride formed by physical vapor deposition, gallium arsenide formed by physical vapor deposition, silicon carbide formed by physical vapor deposition, gallium oxide formed by physical vapor deposition, tin oxide formed by physical vapor deposition, platinum oxide formed by physical vapor deposition, and combinations thereof.

8. The L-shaped field-effect transistor according to claim 4, further comprising at least one of the following:
the mechanically contact portion between the third structure and the second structure overlaps with the mechanically contact portion between the first structure and the second structure;
the first structure and the second structure forms a T-shaped structure;
the width of a portion of the first structure mechanically contacted with the second structure is less than the width of and end of the second structure not mechanically contacted with the second structure; and
the width of a portion of the third structure mechanically contacted with the third branch is equal to the widths of two opposite ends of the third structure.

9. The L-shaped field-effect transistor according to claim 4, further comprising:
a conductor line structure, which is located above the first structure, the second structure, the third structure and the fourth structure, which is also mechanically separately away the first structure, the second structure, the third structure and the fourth structure;
a first conductor line, wherein one end of the first conductor line mechanically contacts with the conductor line structure and another end of the first conductor line only mechanically contacts with the first structure;
a second conductor line, wherein one end of the second conductor line mechanically contacts with the conductor line structure and another end of the second conductive only mechanically contacts with the second structure, wherein mechanical contact between the third structure and the second structure is located at both the mechanical contact between the second conductor line and the second structure and the mechanical contact between the first structure and second structure;
a third conductor line, wherein one end of the third conductor line mechanically contacts with the conductor line structure and another end of the third conductor line only mechanically contacts with the first branch; and
a fourth conductor line, wherein one end of the fourth conductor line mechanically contacts with the conductor line structure and another end of the fourth conductor line only mechanically contacts with the third structure.

10. A method of manufacturing a L-shaped field-effect transistor, comprising:
providing a wafer; and
forming a horizontal field-effect transistor and a vertical filed-effect transistor on the wafer, wherein a source, a gate and a drain of the horizontal field-effect transistor is horizontally arranged on the wafer, and wherein a source, a gate and a drain of the vertical field-effect transistor is vertically arranged on the wafer;
wherein, one end of the vertical field-effect transistor is arranged to mechanically contact with one end of the horizontal field-effect transistor.

11. The method according to claim 10, further comprising at least one of the following:
when the horizontal field-effect transistor and the vertical field-effect transistor are made of different materials, arranging the distance between the gate of the horizontal field-effect transistor and the contact portion between the horizontal field-effect transistor and the vertical field-effect transistor is large than the distribution range of lattice defects in the horizontal field-effect transistor induced by different materials; and
when the horizontal field-effect transistor and the vertical field-effect transistor are made of different materials, arranging the distance between the gate of the vertical field-effect transistor and the contact portion between the vertical field-effect transistor and the horizontal field-effect transistor is large than the distribution range of lattice defects in the vertical field-effect transistor induced by different materials.

12. The method according to claim 10, further comprising at least one of the following:
arranging the horizontal field-effect transistor as a N-type field-effect transistor and arranging the vertical field-effect transistor as a P-type field-effect transistor;
arranging the horizontal field-effect transistor as a P-type field-effect transistor and arranging the vertical field-effect transistor as a N-type field-effect transistor;
arranging the vertical field-effect transistor to be higher than the horizontal field-effect transistor;
arranging the horizontal field-effect transistor to be higher than the vertical field-effect transistor; and
increasing the gate length of the vertical field-effect transistor but not increasing wafer area occupied by the vertical field-effect transistor so as to improve the short channel effect.

13. The method according to claim 10, further comprising at least one of the following:
arranging the horizontal field-effect transistor to be made of silicon and arranging the vertical field-effect transistor to be made of germanium;
arranging the horizontal field-effect transistor to be made of germanium and arranging the vertical field-effect transistor to be made of silicon;
arranging at least one of the horizontal field-effect transistor and the vertical field-effect transistor is made of material selected from the group consisting of the following: single crystal materials formed by epitaxy, materials formed by molecular beam epitaxy, polycrystalline materials formed by deposition, oxide semiconductor materials formed by deposition, materials formed by chemical vapor deposition, materials formed by physical vapor deposition, and combinations thereof;
arranging at least one of the horizontal field-effect transistor and the vertical field-effect transistor is made of material selected from the group consisting of the following: silicon formed by epitaxy, germanium formed by epitaxy, silicon germanium alloy formed by epitaxy, germanium tin alloy formed by epitaxy, gallium nitride formed by epitaxy, gallium arsenide formed by epitaxy, silicon carbide formed by epitaxy, germanium oxide formed by epitaxy, tin oxide formed by epitaxy, alumina formed by epitaxy, and combinations thereof;
arranging at least one of the horizontal field-effect transistor and the vertical field-effect transistor is made of materials selected from the group consisting of the following: silicon formed by molecular beam epitaxy, germanium formed by molecular beam epitaxy, silicon germanium alloys formed by molecular beam epitaxy, germanium tin alloys formed by molecular beam epitaxy, gallium nitride formed by molecular beam epitaxy, gallium arsenide formed by molecular beam epitaxy, silicon carbide formed by molecular beam epitaxy, gallium oxide formed by molecular beam epitaxy, tin oxide formed by molecular beam epitaxy, and platinum oxide formed by molecular beam epitaxy and combinations therefore;
arranging at least one of the horizontal field-effect transistor and the vertical field-effect transistor is made of material selected from the group consisting of the following: silicon formed by chemical vapor deposition, germanium formed by chemical vapor deposition, silicon germanium alloys formed by chemical vapor deposition, germanium tin alloys formed by chemical vapor deposition, gallium nitride formed by chemical vapor deposition, gallium arsenide formed by chemical vapor deposition, silicon carbide formed by chemical vapor deposition, gallium oxide formed by chemical vapor deposition, tin oxide formed by chemical vapor deposition, platinum oxide formed by chemical vapor deposition, and combinations thereof; and
arranging at least one of the horizontal field-effect transistor and the vertical field-effect transistor is made of material selected from the group consisting of the following: silicon formed by physical vapor deposition, germanium formed by physical vapor deposition, silicon germanium alloys formed by physical vapor deposition, germanium tin alloys formed by physical vapor deposition, gallium nitride formed by physical vapor deposition, gallium arsenide formed by physical vapor deposition, silicon carbide formed by physical vapor deposition, gallium oxide formed by physical vapor deposition, tin oxide formed by physical vapor deposition, platinum oxide formed by physical vapor deposition, and combinations thereof.

14. A method of manufacturing a L-shaped field-effect transistor, comprising:
providing a wafer;
providing a first semiconductor material structure and a second semiconductor material structure, wherein the first semiconductor material structure is located on the wafer and has a first branch and a second branch mechanically contacting mutually, wherein the second semiconductor material structure only mechanically contacts with a portion of the second branch; and
providing a conductor-dielectric composite structure, wherein the conductor-dielectric composite structure having a third branch located on the wafer and being mechanically separated away the first semiconductor material structure, a fourth branch located on the wafer and being extended from the third branch across the first branch and mechanically contacted with the first branch at the crossing position, and a fifth branch being extended from the third branch to the neighborhood of the second branch and surrounding a portion of the second semiconductor material structure, wherein the fifth branch and the first semiconductor material structure are mechanically separated mutually;
wherein, the materials of the third branch, the fourth branch and the fifth branch including both the dielectric material located at the bottom and the conductor material located at the top.

15. The method according to claim 14, further comprising at least one of the following:
arranging the thickness of the second semiconductor material structure to be large than the thickness of the first semiconductor material structure;
performing a first patterning process and a second patterning process in sequence after a first semiconductor material layer and a second semiconductor material layer have been formed on the wafer in sequence, wherein the first patterning process transform the first semiconductor material layer into the first semiconductor material structure, wherein both the first patterning process and the second patterning process transform the second semiconductor material layer into the second semiconductor material layer; and
arranging the thickness of the conductor-dielectric composite structure to be less than the thickness of the second semiconductor material structure.

16. The method according to claim 14, further comprising at least one of the following:
arranging the first semiconductor material structure to be made of N-type semiconductor material, and arranging the second semiconductor material structure to be made of P-type semiconductor material;
arranging the first semiconductor material structure to be made of P-type semiconductor material, and arranging the second semiconductor material structure to be made of N-type semiconductor material;
arranging the first semiconductor material structure to be higher than the second semiconductor material structure;
arranging the first semiconductor material structure to be lower than the second semiconductor material structure; and
increasing the thickness of a portion of the fifth branch surrounding the second semiconductor material structure but not increasing the wafer area occupied by the second semiconductor material structure, so as to improve the short channel effect.

17. The method according to claim 14, further comprising at least one of the following:
when the first semiconductor material structure and the second semiconductor structure are made of different semiconductor materials, arranging the distance between the contact portion between the first branch and the fourth branch and the contact portion between the second branch and the second semiconductor material structure to be larger than the distribution range of lattice defects induced by different semiconductor materials in both the second branch and the first branch; and
when the first semiconductor material structure and the second semiconductor material structure are made of different materials, arranging the distance between wherein the fifth branch surrounding the second semiconductor material structure and the contact portion between the second semiconductor material structure and the second branch to be large than the distribution range of lattice defects in the second semiconductor material structure induced by different materials.

18. The method according to claim 14, further comprising at least one of the following:
arranging the first semiconductor material structure to be made of silicon and arranging the second semiconductor material structure to be made of germanium;
arranging the first semiconductor material structure to be made of germanium and arranging the second semiconductor material structure to be made of silicon;
arranging at least one of the first semiconductor material structure and the second semiconductor material structure is made of material selected from the group consisting of the following: single crystal materials formed by epitaxy, materials formed by molecular beam epitaxy, polycrystalline materials formed by deposition, oxide semiconductor materials formed by deposition, materials formed by chemical vapor deposition, materials formed by physical vapor deposition, and combinations thereof;
arranging at least one of the first semiconductor material structure and the second semiconductor material structure is made of material selected from the group consisting of the following: silicon formed by epitaxy, germanium formed by epitaxy, silicon germanium alloy formed by epitaxy, germanium tin alloy formed by epitaxy, gallium nitride formed by epitaxy, gallium arsenide formed by epitaxy, silicon carbide formed by epitaxy, germanium oxide formed by epitaxy, tin oxide formed by epitaxy, alumina formed by epitaxy, and combinations thereof;
arranging at least one of the first semiconductor material structure and the second semiconductor material structure is made of material selected from the group consisting of the following: silicon formed by molecular beam epitaxy, germanium formed by molecular beam epitaxy, silicon germanium alloys formed by molecular beam epitaxy, germanium tin alloys formed by molecular beam epitaxy, gallium nitride formed by molecular beam epitaxy, gallium arsenide formed by molecular beam epitaxy, silicon carbide formed by molecular beam epitaxy, gallium oxide formed by molecular beam epitaxy, tin oxide formed by molecular beam epitaxy, and platinum oxide formed by molecular beam epitaxy and combinations therefore;
arranging at least one of the first semiconductor material structure and the second semiconductor material structure is made of material selected from the group consisting of the following: silicon formed by chemical vapor deposition, germanium formed by chemical vapor deposition, silicon germanium alloys formed by chemical vapor deposition, germanium tin alloys formed by chemical vapor deposition, gallium nitride formed by chemical vapor deposition, gallium arsenide formed by chemical vapor deposition, silicon carbide formed by chemical vapor deposition, gallium oxide formed by chemical vapor deposition, tin oxide formed by chemical vapor deposition, platinum oxide formed by chemical vapor deposition, and combinations thereof; and
arranging at least one of the first semiconductor material structure and the second semiconductor material structure is made of material selected from the group consisting of the following: silicon formed by physical vapor deposition, germanium formed by physical vapor deposition, silicon germanium alloys formed by physical vapor deposition, germanium tin alloys formed by physical vapor deposition, gallium nitride formed by physical vapor deposition, gallium arsenide formed by physical vapor deposition, silicon carbide formed by physical vapor deposition, gallium oxide formed by physical vapor deposition, tin oxide formed by physical vapor deposition, platinum oxide formed by physical vapor deposition, and combinations thereof.

19. The method according to claim 14, further comprising at least one of the following:
arranging the mechanical contact portion between the second semiconductor material structure and the second branch overlaps the mechanical contact portion between the first branch and the second branch;
arranging the first semiconductor material structure to be T-shaped distributed on the wafer;
arranging the width of the mechanical contact portion between the first branch and the four branch is less than one end of the first branch not mechanically contacted with the second branch; and
arranging the width of the mechanical contact portion between the second semiconductor material structure and the fifth branch is equal to the width of the two opposite ends of the second semiconductor material structure.

20. The method according to claim 14, further comprising:
forming a first conductor line, a second conductor line, a third conductor line and a fourth conductor line, wherein a first end of the first conductor line only mechanically contacts with the first branch, wherein a first end of the second conductor line only mechanically contacts with the second branch, wherein a first end of the third conductor line only mechanically contacts with the second semiconductor material structure, and wherein a first end of the fourth conductor line only mechanically contacts with the conductor-dielectric composite layer; and
forming a conductor line structure which located above the first semiconductor material structure, the second semiconductor material structure and the conductor-dielectric composite layer and mechanically separated away them, wherein a second end of the first conductor line mechanically contacts with the conductor line structure, wherein a second end of the second conductor line mechanically contacts with the conductor line structure, wherein a second end of the third conductor line mechanically contacts with the conductor line structure, wherein a second end of the four conductor line mechanically contacts with the conductor line structure, and wherein the contact portion between the second semiconductor material structure and the second branch is more close to the mechanical contact portion between the first branch and the second branch than the mechanical contact portion between the second conductor line and the second branch.
